(19) United States
(12) Patent Application Publication
(10) Pub. No.: US 2013/0275063 A1
(43) Pub. Date: Oct. 17, 2013

(54) SYSTEM FOR DETECTING PARTIAL DISCHARGE SIGNAL AND METHOD THEREOF

(71) Applicant: LSIS CO., LTD., Anyang-si (KR)

(72) Inventors: Do Hoon LEE, Cheongju-si (KR); Chan Yong Park, Busan (KR); Jong Ung Choi, Cheongwon-gun (KR)

(73) Assignee: LSIS CO., LTD., Anyang-si (KR)

(21) Appl. No.: 13/850,130

(22) Filed: Mar. 25, 2013

(30) Foreign Application Priority Data
Apr. 13, 2012 (KR) 10-2012-0038616

(51) Int. Cl. G01R 29/26

(52) U.S. Cl. CPC G01R 29/26
USPC 702/58

(57) ABSTRACT

A system for detecting a partial discharge signal comprises a signal detecting unit configured to detect a partial discharge signal and a noise signal of an electric power equipment; a communicating unit configured to transmit the detected partial discharge signal and noise signal through a communication network; a control unit configured to determine a level of risk of the partial discharge signal on the basis of analysis results of a partial discharge signal trend analysis algorithm and a partial discharge signal pattern analysis algorithm when the partial discharge signal transmitted through the communication network is greater than the noise signal; and a display unit configured to display the determined level of risk.

### CROSS-REFERENCE TO RELATED APPLICATION

Pursuant to 35 U.S.C. §119(a), this application claims the benefit of earlier filing date and right of priority to Korean Application No. 10-2012-0038616, filed on Apr. 13, 2012, the contents of which is incorporated by reference herein in its entirety.

### BACKGROUND OF THE INVENTION

1. Field of the Invention

The present disclosure relates to a system for detecting a partial discharge (abbreviated as PD hereinafter) signal and a method thereof.

2. Background of the Invention

In general, in order to measure a PD signal of an electric power equipment, the PD signal is measured by using a coupler connected to a high voltage part of the electric power equipment (machinery) and a sensor of a HFCT (High Frequency Current Transformer) or a RFCT (Radio Frequency Current Transformer). However, in the case of connecting a coupler to the high voltage part of the electric power equipment and applying the same to a high capacity/high voltage equipment, the coupler is hugely increased in size and costly. Also, since the coupler is directly connected to the high voltage part of the electric power equipment, the coupler may be exploded occasionally. Disclosure of an apparatus for wirelessly detecting a partial discharge of an electric power equipment according to a related art may be referred to content disclosed in Korean Patent Laid Open No. 10-2010-0125811.

### SUMMARY OF THE INVENTION

Therefore, an aspect of the detailed description is to provide a system for detecting a partial discharge signal capable of automatically finally determining a level of risk of a PD signal of a power equipment by combining results of the PD signal pattern analysis {e.g., a PRPD (Phase Resolved Partial Discharge) or a PRPS (Phase Resolved Pulse Sequence)} and results of a PD signal trend analysis, and informing a user accordingly, thus providing automated operation and enhancing reliability of PD diagnosis, and a method thereof.

To achieve these and other advantages and in accordance with the purpose of this disclosure, as embodied and broadly described herein, a system for detecting a partial discharge signal, the system comprising:

a signal detecting unit configured to detect a partial discharge signal and a noise signal of an electric power equipment;

a communicating unit configured to transmit the detected partial discharge signal and noise signal through a communication network;

a control unit configured to determine a level of risk of the partial discharge signal on the basis of analysis results of a partial discharge signal trend analysis algorithm and a partial discharge signal pattern analysis algorithm when the partial discharge signal transmitted through the communication network is greater than the noise signal; and

a display unit configured to display the determined level of risk.

According to an aspect of the present invention, the partial discharge signal pattern analysis algorithm may be a PRPD (Phase Resolved Partial Discharge) analysis algorithm or a PRPS (Phase Resolved Pulse Sequence) analysis algorithm.

According to another aspect of the present invention, when the partial discharge signal is greater than the noise signal and the partial discharge signal exceeds an allowable risk reference value, a slope of the partial discharge signal may be calculated, and when the slope of the partial discharge signal is equal to or greater than a predetermined caution level reference value, the control unit may determine a level of risk of the partial discharge signal, as caution level.

According to still another aspect of the present invention, the control unit may display a predetermined event and/or alarm corresponding to the caution level on the display unit.

According to still aspect of the present invention, when the partial discharge signal is greater than the noise signal and the partial discharge exceeds an predetermined danger level reference value, the control unit may calculate a slope of the partial discharge signal, and when the slope is equal to or greater than the predetermined danger level reference value, the control unit may determine a level of risk of the partial discharge signal, as danger level or risk level.

According to still aspect of the present invention, the control unit may display a predetermined event and/or alarm corresponding to the danger level or risk level on the display unit.

According to still aspect of the present invention, when the partial discharge signal is greater than the noise signal and the partial discharge signal exceeds the allowable risk reference value, the control unit may calculate time intervals at which the partial discharge signal is generated, and when the time intervals at which the partial discharge signal is generated is reduced to within a predetermined caution level interval, the control unit may determine a level of risk of the partial discharge signal, as caution level.

According to still aspect of the present invention, when the partial discharge signal is greater than the noise signal and the partial discharge signal exceeds the allowable risk reference value, the control unit may calculate time intervals at which the partial discharge signal is generated, and when the time intervals at which the partial discharge signal is generate is reduced to within a predetermined danger level interval, the control unit may determine a level of risk of the partial discharge signal, as danger level or risk level.

To achieve these and other advantages and in accordance with the purpose of this disclosure, as embodied and broadly described herein, a method for detecting a partial discharge signal, the method comprising:

detecting a partial discharge signal and a noise signal of an electric power equipment;

transmitting the detected partial discharge signal and noise signal through a communication network;

when the partial discharge signal transmitted through the communication network is greater than the noise signal, determining a level of risk of the partial discharge signal on the basis of analysis results of a partial discharge signal trend analysis algorithm and a partial discharge signal pattern analysis algorithm; and

displaying the determined the level of risk on a display unit.

Further scope of applicability of the present application will become more apparent from the detailed description given hereinafter. However, it should be understood that the detailed description and specific examples, while indicating preferred aspects of the invention, are given by way of illustration only, since various changes and modifications within the spirit and scope of the invention will become apparent to those skilled in the art from the detailed description.

### BRIEF DESCRIPTION OF THE DRAWINGS

The accompanying drawings, which are included to provide a further understanding of the invention and are incorporated in and constitute a part of this disclosure, illustrate exemplary embodiments and together with the description serve to explain the principles of the invention.

In the drawings:

FIG. 1 is a block diagram of a system for detecting a partial discharge signal according to a preferred embodiment of the present invention.

FIGS. 2 and 3 are flow charts illustrating a process of a method for detecting a partial discharge signal according to an embodiment of the present invention.

FIG. 4 is a flow chart illustrating a process of a method for detecting a partial discharge signal according to another embodiment of the present invention.

### DETAILED DESCRIPTION OF THE INVENTION

Description will now be given in detail of the exemplary embodiments, with reference to the accompanying drawings. For the sake of brief description with reference to the drawings, the same or equivalent components will be provided with the same reference numbers, and description thereof will not be repeated.

In describing the present invention, if a detailed explanation for a related known function or construction is considered to unnecessarily divert the gist of the present invention, such explanation will be omitted but would be understood by those skilled in the art. Also, similar reference numerals are used for the similar parts throughout the disclosure.

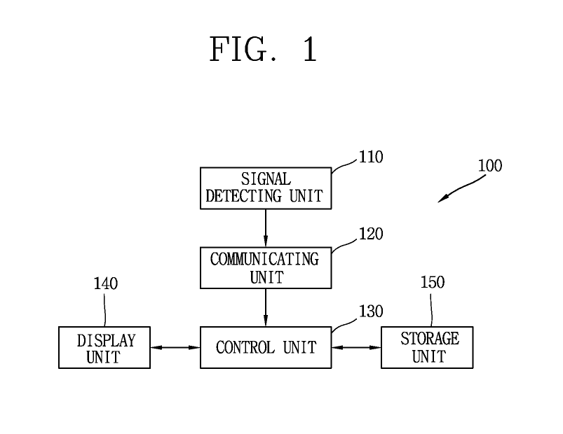

Hereinafter, a system for detecting a partial discharge signal capable of finally determining a level of risk of a partial discharge (PD) signal by a combination of a partial discharge signal trend analysis algorithm and a PRPD (Phase Resolved Partial Discharge) or a PRPS (Phase Resolved Pulse Sequence) analysis algorithm, and providing an event or alarm to the user according to the determined level of risk, and a method thereof will be described with reference to FIGS. 1 through 4.

FIG. 1 is a block diagram of a system for detecting a partial discharge signal according to an embodiment of the present invention.

As illustrated in FIG. 1, a system 100 for detecting a partial discharge signal according to an embodiment of the present invention includes a signal detecting unit 110 configured to measure (or detecting) a partial discharge signal and a noise signal of an electric power equipment (e.g., an electric power apparatus such as a circuit breaker, switchgear, etc.), a communicating unit 120 configured to transmit the measured PD signal (abbreviated as PDM signal hereinafter) and noise signal (abbreviated as NGM signal hereinafter) through a communication network; a control unit 130 configured to determine a level of risk of the PD signal on the basis of analysis results of a PD signal trend analysis algorithm and a PD signal pattern analysis algorithm (e.g., PRPD or PRPS) when the PDM value transmitted through the communication network is greater than the NGM value; and a display unit 140 configured to display the determined level of risk.

The system 100 for detecting a PD signal according to an embodiment of the present invention may further include a storage unit 150 configured to store the PDM value and the NGM value transmitted through the communication network, the PD signal trend analysis algorithm, the PD signal pattern analysis algorithm (e.g., PRDP or PRPS), and the like.

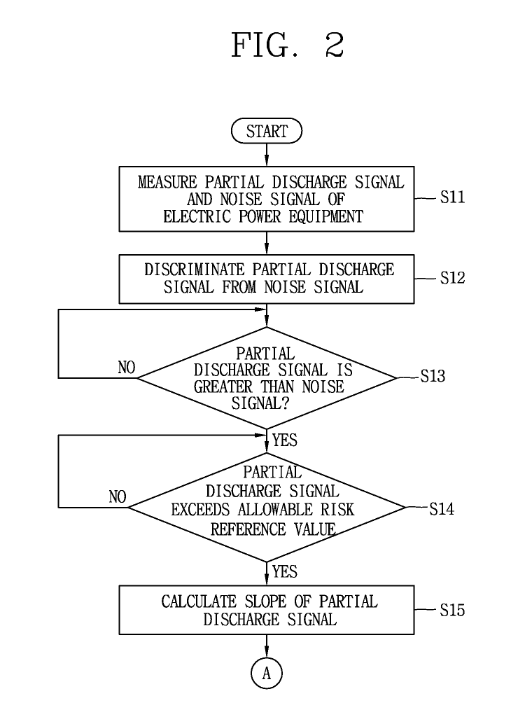

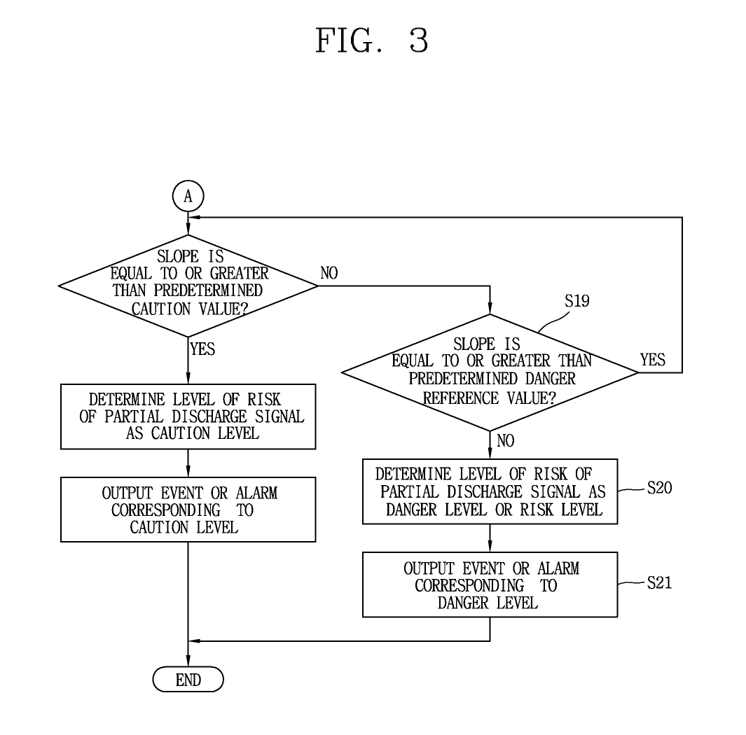

FIGS. 2 and 3 are flow charts illustrating a process of a method for detecting a PD signal according to an embodiment of the present invention.

First, the signal detecting unit 110 measures (or detects) a PD signal and a noise signal of the electric power equipment, and outputs the PDM value and the NGM value to the control unit 130 through the communicating unit 120 (S11). For example, a PD signal and a noise signal are measured by using the signal detecting unit 110 such as a coupler, an HFCT sensor, an RFCT sensor, or the like, connected to a high voltage part of the electric power equipment, and the PDM value and the NGM value are output to the control unit 130.

The control unit 130 compares the PDM value and the NGM value to discriminate (in other words to do noise gating) a PD signal (an intrinsic PD signal) from a noise signal (S12), and determines whether the PD signal is greater than the noise signal (S13).

When the PD signal is greater than the noise signal, the control unit 130 determines a level of risk of the PD signal by combining the PD signal trend analysis algorithm and the PD signal pattern analysis algorithm (e.g., the PRPD or the PRPS) as follows.

When the PD signal is greater than the noise signal, the control unit 130 determines whether the PD signal exceeds an allowable risk reference value (S14). For example, the control unit 130 may determine whether the PD signal exceeds the allowable risk reference value through the PRPD (or PRPS) analysis algorithm. Here, the PRPD or PRPS analysis algorithm has been already known, so a detailed description thereof will be omitted.

When the PD signal exceeds the allowable risk reference value, the control unit 130 performs the PD trend analysis algorithm as follows.

The control unit 130 calculates a slope of the PD signal (e.g., a PD trend graph) (S15), and determines whether the slope is equal to or greater than a predetermined caution level reference value (S16).

When the slope is equal to or greater than the predetermined caution level reference value, the control unit 130 determines a level of risk of the PD signal as a caution level (i.e., as being cautious) (or PD trend caution level) (S17) and outputs predetermined information (event and/or alarm) corresponding to the determined caution level to the display unit 140 (S18).

The control unit 130 determines whether the slope of the PD signal (e.g., the PD trend graph) is equal to or greater than a predetermined danger reference value (or a predetermined risk reference value) (S19). When the slope of the PD signal (e.g., the PD trend graph) is equal to or greater than the predetermined danger reference value, the control unit 130 determines a level of the PD signal, as danger level (or PD trend danger level) or risk level (S20) and outputs predetermined information (event and/or alarm) corresponding to the determined danger level or risk level to the display unit 140 (S21). The predetermined caution level reference value or the predetermined danger reference (or risk) value may be changed according to a kind of the electric power equipment or a designer's intention.

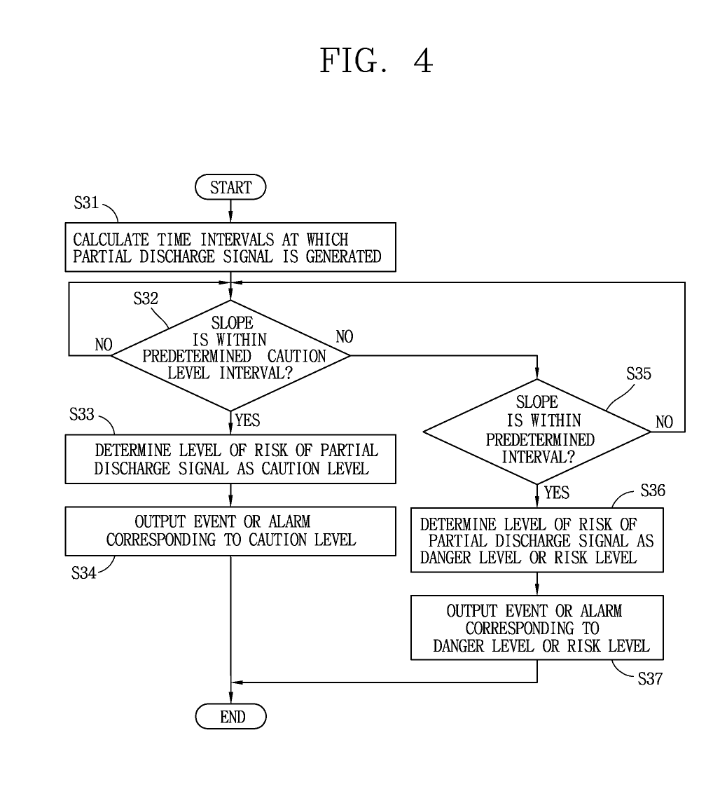

Meanwhile, the control unit 130 may determine a level of risk of the PD signal on the basis of time intervals at which the PD signal is generated. This will be described with reference to FIG. 4.

FIG. 4 is a flow chart illustrating a process of a method for detecting a PD signal according to another embodiment of the present invention.

First, the signal detecting unit 110 measures (or detects) a PD signal and a noise signal of an electric power equipment (e.g., an electric power machinery), and outputs the PDM value and the NGM value to the control unit 130 through the communicating unit 120. For example, a PD signal and a noise signal are measured by using the signal detecting unit 110 such as a coupler, an HFCT sensor, an RFCT sensor, or the like, connected to a high voltage part of the electric power equipment, and the PDM value and the NGM value are output to the control unit 130.

The control unit 130 compares the PDM value and the NGM value to discriminate (in other words to do noise gating) a PD signal (an intrinsic PD signal) from a noise signal, and determines whether the PD signal is greater than the noise signal.

When the PD signal is greater than the noise signal, the control unit 130 determines a level of risk of the PD signal by combining the PD signal trend analysis algorithm and the PD signal pattern analysis algorithm (e.g., the PRPD or the PRPS) as follows.

When the PD signal is greater than the noise signal, the control unit 130 determines whether the PD signal exceeds an allowable risk reference value. For example, the control unit 130 may determine whether the PD signal exceeds the allowable risk reference value through the PRPD (or PRPS) analysis algorithm.

When the PDD signal exceeds the allowable risk reference value, the control unit 130 performs the PD trend analysis algorithm as follows.

The control unit 130 calculates time intervals at which the PD signal is generated (S31), and determines whether the generated time intervals are reduced to within a predetermined caution level interval (S32).

When the generated time intervals are reduced to within a predetermined caution level interval, the control unit 130 determines a level of risk of the PD signal, as caution level (PD trend caution level) (S33) and outputs predetermined information (event and/or alarm) corresponding to the determined caution level to the display unit 140 (S34).

The control unit 130 determines whether the generated time intervals are reduced to within a predetermined danger (or risk) interval (S35). When the generated time intervals are reduced to within a predetermined danger (or risk) interval, the control unit 130 determines a level of risk of the PD signal, as danger level (PD trend danger level) or risk level (S36), and outputs predetermined information (event and/or alarm) corresponding to the determined danger level or risk level to the display unit 140 (S37). The predetermined caution level intervals and the predetermined risk intervals may be changed according to a kind of the electric power equipment or a designer's intention.

Meanwhile, when a single defect pattern probability is equal to or greater than a predetermined value through an existing PRPD (or PRPS) analysis, the PD pattern analysis algorithm proposed in the present invention determines a level of risk (i.e., caution level or danger level) based on the determined on the determined defect, and when two types of pattern probabilities are all equal to or greater than 40% (e.g., a floating electrode: 45% and surface defect of insulator: 44%), the PD pattern analysis algorithm proposed in the present invention may perform again a PRPS analysis using a multi-pattern library to determine a level of risk (i.e., caution level or danger level) based on the re-determined defect.

As described above, in the case of the system for detecting a PD signal and the method thereof according to embodiments of the present invention, a level of a PD signal of an electric power equipment is finally automatically determined by combining the PD pattern analysis (e.g., PRPD or PRPS) results and the PD signal trend analysis results, and corresponding information is provided to a user. In this manner, the system for detecting a PD signal can be automated and reliability of PD diagnosis can be enhanced.

The foregoing embodiments and advantages are merely exemplary and are not to be considered as limiting the present disclosure. The present teachings can be readily applied to other types of apparatuses. This description is intended to be illustrative, and not to limit the scope of the claims. Many alternatives, modifications, and variations will be apparent to those skilled in the art. The features, structures, methods, and other characteristics of the exemplary embodiments described herein may be combined in various ways to obtain additional and/or alternative exemplary embodiments.

As the present features may be embodied in several forms without departing from the characteristics thereof, it should also be understood that the above-described embodiments are not limited by any of the details of the foregoing description, unless otherwise specified, but rather should be considered broadly within its scope as defined in the appended claims, and therefore all changes and modifications that fall within the metes and bounds of the claims, or equivalents of such metes and bounds are therefore intended to be embraced by the appended claims.

What is claimed is:

1. A system for detecting a partial discharge signal, the system comprising:
a signal detecting unit configured to detect a partial discharge signal and a noise signal of an electric power equipment;
a communicating unit configured to transmit the detected partial discharge signal and noise signal through a communication network;
a control unit configured to determine a level of risk of the partial discharge signal on the basis of analysis results of a partial discharge signal trend analysis algorithm and a partial discharge signal pattern analysis algorithm when the partial discharge signal transmitted through the communication network is greater than the noise signal; and
a display unit configured to display the determined level of risk.

2. The system of claim 1, wherein the partial discharge signal pattern analysis algorithm is a phase resolved partial discharge (PRPD) analysis algorithm or a phase resolved pulse sequence (PRPS) analysis algorithm.

3. The system of claim 1, wherein when the partial discharge signal is greater than the noise signal and the partial discharge signal exceeds an allowable risk reference value, a slope of the partial discharge signal is calculated, and when the slope of the partial discharge signal is equal to or greater than a predetermined caution level reference value, the control unit determines a level of risk of the partial discharge signal, as a caution level, and
when the slope is equal to or greater than a predetermined danger level reference value, the control unit determines a level of risk of the partial discharge signal, as a danger level or a risk level.

4. The system of claim 3, wherein the control unit displays a predetermined event and/or alarm corresponding to the caution level on the display unit, and
displays a predetermined event and/or alarm corresponding to the danger level or risk level on the display unit.

5. The system of claim 1, wherein when the partial discharge signal is greater than the noise signal and the partial discharge signal exceeds the allowable risk reference value, the control unit calculates time intervals at which the partial discharge signal is generated, and when the time intervals at which the partial discharge signal is generate is reduced to within a predetermined caution level interval, the control unit determines a level of risk of the partial discharge signal, as caution level, and
when the time intervals at which the partial discharge signal is generated is reduced to within a predetermined danger level interval, the control unit determines a level of risk of the partial discharge signal, as danger level or risk level.

6. A method for detecting a partial discharge signal, the method comprising:
detecting a partial discharge signal and a noise signal of an electric power equipment;
transmitting the detected partial discharge signal and noise signal through a communication network;
when the partial discharge signal transmitted through the communication network is greater than the noise signal, determining a level of risk of the partial discharge signal on the basis of analysis results of a partial discharge signal trend analysis algorithm and a partial discharge signal pattern analysis algorithm; and
displaying the determined the level of risk on a display unit.
